(19) United States
(12) Patent Application Publication
(10) Pub. No.: US 2005/0162238 A1
(43) Pub. Date: Jul. 28, 2005

(54) Structure of a wave filter

(76) Inventor: Chung-Shun Ho, Yung Kang City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/762,271

(22) Filed: Jan. 23, 2004

(51) Int. Cl. H03H 7/01

(52) U.S. Cl. 333/185

(57) ABSTRACT

A first embodiment of a filter includes a circuit board, a metallic tube, and a metallic cap; the tube has an annular groove on outer side of first end, and a leak-stoppage ring fitted onto the groove; the board is held in the tube, and is secured to the tube by solder; the cap is tightly fitted around the first end of the tube such that the board is protected, and the leak-stoppage ring is sandwiched between the cap and the tube; in a second embodiment, annular groove is formed on outer side of a fitting end portion of the cap instead, and leak-stoppage ring is fitted onto the groove; the board is partially held in the cap, and is secured to the cap by solder; the tube is tightly fitted around the cap such that the board is protected, and the ring is sandwiched between the cap and the tube.

### BACKGROUND OF THE INVENTION

1. Field of the invention

The present invention relates to a wave filter, more particularly one, which is made such that the circuit board thereof is firmly held in the holding tube part and can be effectively grounded, and such that a leak-stoppage ring can be easily fitted in proper position to function effectively.

2. Brief Description of the Prior Art

Referring to FIGS. 5 and 6, a conventional wave filter consists of a circuit board 6, a metallic holding tube 7, and a metallic cap 8.

The circuit board 6 includes a substrate 61, electronic parts (not numbered) on the substrate 61, a connecting head 62 joined to one end of the substrate 61 by means of welding, and a lead 63 joined to the other end of the substrate 61 by means of welding. Furthermore, two thin elastic elements 64 are connected to a lateral edge of the substrate 61 by means of welding.

The holding tube 7 has an end portion 71, screw threads on an outer side of the end portion 71, an insulating ring 72 fitted in the end portion 71, and a fitting end portion 73 at the other end. The circuit board 6 is held in the holding tube 7 with the connecting head 62 being received in the end portion 71, and with the thin elastic elements 62 touching the inner side of the holding tube 7 to make the circuit board 6 grounded.

The cap 8 has tube-shaped end portions 83 and 85 at two ends, a separating part 81 disposed between the tube-shaped end portions 83 and 85 as well as connected to an inner side, an insulating ring 82 secured within the separating part 81, and a leak-stoppage gasket 86 positioned in the tube-shaped end portion 85 and over the separating part 81. The fitting end portion 73 of the holding tube 7 is tightly fitted in the tube-shaped end portion 85 of the cap 8, and tightly pressed against the leak-stoppage gasket 86.

In assembling the filter, the circuit board 6 is fitted in the holding tube 7 such that the elastic elements 64 touch the tube 7 to make the circuit board 6 grounded, and help the same held steady. And, the fitting end portion 73 is inserted in the end portion 85 of the cap 8 to be secured in the same after the leak-stoppage gasket 86 is held in the end portion 85. Thus, the lead 63 passes through the insulating ring 82, and projects outwards from the cap 8. And, the circuit board 6 is steady in the holding tube 7.

However, the above wave filter is found to have the following disadvantages:

1. The circuit board 6 is grounded and held steady with the help of the thin elastic elements 64. And, fatigue of the elastic elements 64 will be present after the wave filter has been used for extended period of time. Consequently, the circuit board 6 can't be effectively grounded or held steady, and the wave filter can't function properly.

2. The leak-stoppage gasket 86 might be displaced relative to the separating part 81, and partially pressed against the inner side of the fitting tube-shaped portion 85 when the fitting end portion 73 is being inserted in the portion 85. Therefore, it is more difficult to assemble the wave filter properly.

3. Leakage will happen in case the leak-stoppage gasket 86 is partially pressed against the inner side of the tube-shaped portion 85 or the fitting end portion 73 isn't pressed against the separating part 81 with uniform force.

### SUMMARY OF THE INVENTION

It is a main object of the present invention to provide a wave filter to overcome the above disadvantages.

A first embodiment of the wave filter includes a circuit board, a metallic tube, and a metallic cap; the tube has an annular groove on outer side of first end, and a leak-stoppage ring fitted onto the groove; the board is held in the tube, and is secured to the tube by solder; the cap is tightly fitted around the first end of the tube such that the board is protected, and the leak-stoppage ring is sandwiched between the cap and the tube; in a second embodiment, annular groove is formed on outer side of a fitting end portion of the cap instead, and leak-stoppage ring is fitted onto the groove; the board is partially held in the cap, and is secured to the cap by solder; the tube is tightly fitted around the cap such that the board is protected, and the ring is sandwiched between the cap and the tube. Thus, the circuit boards are effectively grounded, and the leak-stoppage rings can be easily fitted in proper position, and function properly.

### BRIEF DESCRIPTION OF THE DRAWINGS

The present invention will be better understood by referring to the accompanying drawings, wherein:

FIG. 1 is an exploded perspective view of the first embodiment in the present invention,

FIG. 2 is a vertical section of the first embodiment,

FIG. 3 is an exploded perspective view of the second embodiment in the present invention,

FIG. 4 is a vertical section of the second embodiment,

FIG. 5 is an exploded perspective view of the conventional wave filter as described in the Background, and

FIG. 6 is a vertical section of the conventional wave filter.

### DETAILED DESCRIPTION OF THE PREFERRED EMBODIMENTS

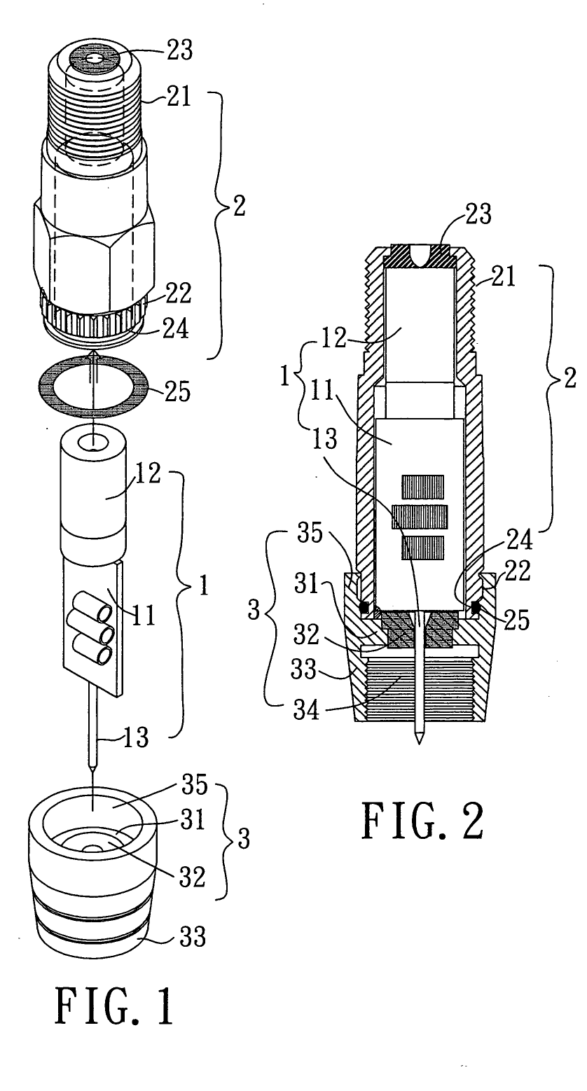

Referring to FIGS. 1 and 2, a first embodiment of a wave filter in the present invention includes a circuit board 1, a metallic holding tube 2, and a metallic cap 3.

The circuit board 1 includes a substrate 11, electronic parts (not numbered) connected to the substrate 11 by means of solder welding, a connecting head 12 joined to one end of the substrate 11 by means of solder welding, and a lead 13 joined to the other end of the substrate 11 by means of solder welding.

The holding tube 2 has a first end portion 21, screw threads on an outer side of the end portion 21, an insulating ring 23 fitted in the end portion 21, a fitting end portion 22 at the other end, and an annular groove 24 on an outer side of the fitting end portion 22. The circuit board 1 is held in the holding tube 2 with the connecting head 12 being received in the end portion 21. In addition, a leak-stoppage ring 25 is fitted onto the annular groove 24. The substrate 11 is secured to the inner side of the holding tube 2 by means of solder welding therefore it is grounded through the solder and the holding tube 2.

The cap 3 includes tube-shaped end portions 33 and 35 at two ends, and has a separating part 31 disposed between the end portions 33 and 35 as well as secured to an inner side thereof, an insulating ring 32 secured within the separating part 31. The fitting end portion 22 of the holding tube 2 is tightly fitted in the tube-shaped end portion 35 of the cap 5 such that the leak-stoppage ring 25 is tightly pressed against inner side of the cap 3.

In assembling the filter, the ring 25 is fitted onto the groove 24, and the circuit board 1 is inserted in the holding tube 2. Then, the circuit board 1 is secured to the holding tube 2 by means of solder welding. And, the fitting end portion 22 is tightly fitted in the end portion 35 of the cap 5. Thus, the lead 13 passes through the insulating ring 32, and projects outwards from the cap 3. And, the leak-stoppage ring 25 is tightly pressed against the inner side of the cap 3, and can function effectively.

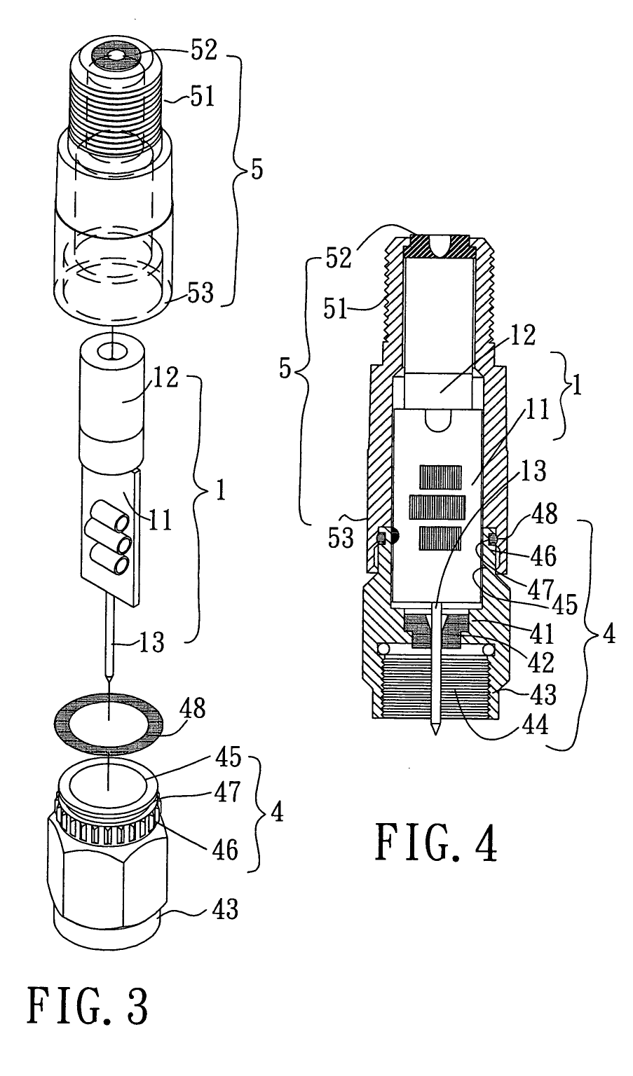

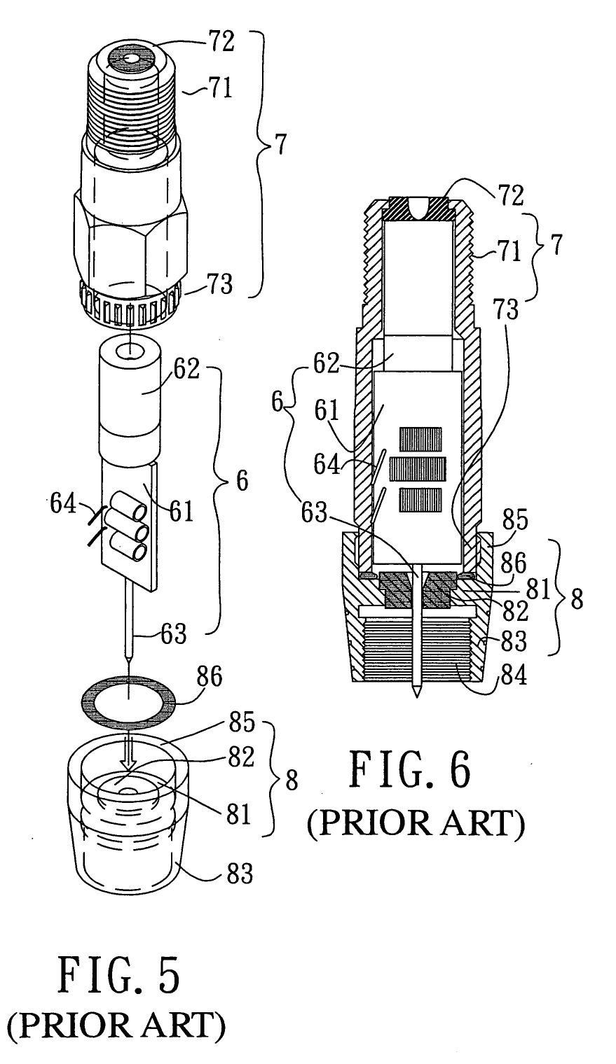

Referring to FIGS. 3 and 4, a second embodiment of a wave filter in the present invention includes a circuit board 1, a metallic holding tube 5, and a metallic cap 4.

The circuit board 1 includes a substrate 11, electronic parts on the substrate 11, a connecting head 12 joined to one end of the substrate 11 by means of solder welding, and a lead 13 joined to the other end of the substrate 11 by means of solder welding.

The holding tube 5 has a first end portion 51, screw threads on an outer side of the first end portion 51, an insulating ring 52 fitted in the end portion 21, and a fitting end portion 22 at the other end.

The cap 4 includes tube-shaped end portions 43 and 45 at two ends. A separating part 41 is disposed between the end portions 43 and 45 of the cap 4, and is secured to an inner side of the cap 4. And, an insulating ring 42 is secured within the separating part 41. The tube-shaped end portion 45 of the cap 4 has a fitting portion 46, whose outer side is formed with an annular groove 47. In addition, a leak-stoppage ring 48 is fitted onto the annular groove 47. The substrate 11 is partially held in the end portion 45 of the cap 4, and is secured to inner side of the fitting portion 46 by means of solder welding therefore it is grounded through the solder as well as the cap 4. The fitting end portion 53 of the holding tube 5 is tightly fitted around the fitting portion 46 of the cap 4 such that the leak-stoppage ring 48 is tightly pressed against the inner side of the holding tube 5.

In assembling the filter, the leak-stoppage ring 48 is fitted onto the annular groove 47, and the circuit board 1 is fitted to the tube-shaped end portion 45 of the cap 4 such that the lead 13 passes through the insulating ring 42, and projects outwards from the cap 4. Then, the circuit board 1 is secured to the cap 4 by means of solder welding. And, the holding tube 5 is tightly fitted around the fitting portion 46 of the cap 4 at the fitting end portion 53 thereof with the first end portion 51 holding the connecting head 12 of the circuit board 1 therein. Thus, the leak-stoppage ring 48 is tightly sandwiched between the holding tube 5 and the cap 4, and can function effectively.

From the above description, it can be easily understood that the wave filters of the present invention have advantages as followings:

1. The circuit boards can be secured in position without chance of getting loose, and can be effectively grounded because they are connected with the holding tube, and the cap by solder welding.

2. The leak-stoppage rings are first tightly fitted onto the annular grooves therefore there in no chance for the leak-stoppage rings to be displaced, and the filters can be properly assembled with ease.

3. For the same reason as mentioned above, the holding tubes can't displace the leak-stoppage rings when they are being fitted to the caps. Therefore, it is not difficult to assemble the filters properly.

4. The leak-stoppage rings are tightly sandwiched between the holding tubes and the caps therefore they can stop water from flowing into the filters effectively.

1. Structure of a wave filter, comprising
a circuit board including a substrate, and electronic parts on the substrate; the substrate having a connecting head, and a lead respectively secured to two ends thereof by means of solder welding;
a metallic holding tube having a first end portion, and a fitting end portion at other end; the first end portion having screw threads on an outer side thereof, and an insulating ring fitted therein; the fitting end portion having an annular groove on an outer side thereof, and a leak-stoppage ring fitted onto the annular groove; and
a metallic cap having first and second tube-shaped end portions at two ends thereof; the cap having a separating part disposed between the tube-shaped end portions and secured to an inner side thereof; the cap having an insulating ring secured within the separating part thereof; the second tube-shaped end portion having screw threads on an inner side;
the circuit board being held in the holding tube with the connecting head being received in the threaded first end portion of the holding tube; the substrate being secured to an inner side of the holding tube by means of solder welding such that the circuit board is grounded;
the fitting end portion of the holding tube being tightly fitted in the first tube-shaped end portion of the cap such that the leak-stoppage ring is tightly sandwiched between the cap and the holding tube; the lead of the circuit board passing through the insulating ring of the cap, and projecting outwards from the cap.

2. Structure of a wave filter, comprising
a circuit board including a substrate, and electronic parts on the substrate; the substrate having a connecting head, and a lead respectively secured to two ends thereof by means of solder welding; a metallic holding tube having a first end portion, and a fitting end portion at other end; the first end portion having screw threads on an outer side thereof, and an insulating ring fitted therein; and a metallic cap having first and second tube-shaped end portions at two ends thereof; the cap having a separating part disposed between the tube-shaped end portions and secured to an inner side thereof; the cap having an insulating ring secured within the separating part thereof; the second tube-shaped end portion having screw threads on an inner side; the circuit board being held in the holding tube with the connecting head being received in the threaded first end portion of the holding tube; the fitting end portion of the holding tube being tightly fitted in the first tube-shaped end portion of the cap; the lead passing through the insulating ring of the cap, and projecting outwards from the cap; and having characteristics that the fitting end portion of the holding tube has an annular groove on an outer side, and that a leak-stoppage ring is fitted onto the annular groove such that the leak-stoppage ring is tightly sandwiched between the cap and the holding tube.

3. Structure of a wave filter, comprising
a circuit board including a substrate, and electronic parts on the substrate; the substrate having a connecting head, and a lead respectively secured to two ends thereof by means of solder welding;
a metallic cap having first and second tube-shaped end portions at two ends thereof; the cap having a separating part disposed between the tube-shaped end portions and secured to an inner side thereof; the cap having an insulating ring secured within the separating part thereof; the first tube-shaped end portion having an annular groove on an outer side thereof, and a leak-stoppage ring fitted onto the annular groove; the second tube-shaped end portion having screw threads on an inner side;
a metallic holding tube having a first end portion, and a fitting end portion at other end; the first end portion having screw threads on an outer side thereof, and an insulating ring fitted therein;
the substrate of the circuit board being partially held in the first tube-shaped end portion of the cap with the lead passing through the insulating ring of the cap, and projecting outwards from the cap;
the fitting end portion of the holding tube being tightly fitted around the first tube-shaped end portion of the cap such that the leak-stoppage ring is tightly sandwiched between the cap and the holding tube, and such that the connecting head is received in the threaded first end portion of the holding tube.

4. Structure of a wave filter, comprising
a circuit board including a substrate, and electronic parts on the substrate; the substrate having a connecting head, and a lead respectively secured to two ends thereof by means of solder welding;
a metallic cap having first and second tube-shaped end portions at two ends thereof; the cap having a separating part disposed between the tube-shaped end portions and secured to an inner side thereof; the cap having an insulating ring secured within the separating part thereof; the first tube-shaped end portion having an annular groove on an outer side thereof, and a leak-stoppage ring fitted onto the annular groove; the second tube-shaped end portion having screw threads on an inner side;
a metallic holding tube having a first end portion, and a fitting end portion at other end; the first end portion having screw threads on an outer side thereof, and an insulating ring fitted therein;
the substrate of the circuit board being partially held in the first tube-shaped end portion of the cap with the lead passing through the insulating ring of the cap, and projecting outwards from the cap; the substrate being secured to an inner side of the first tube-shaped end portion of the cap by means of solder welding such that the circuit board is grounded;
the fitting end portion of the holding tube being tightly fitted around the first tube-shaped end portion of the cap such that the leak-stoppage ring is tightly sandwiched between the cap and the holding tube, and the connecting head is received in the threaded first end portion of the holding tube.
